(19) United States
(12) Patent Application Publication
(10) Pub. No.: US 2025/0210838 A1
(43) Pub. Date: Jun. 26, 2025

(54) TM-MODE DIELECTRIC FILTER

(71) Applicant: Suzhou Luxshare Technology Co., Ltd., Suzhou City (CN)

(72) Inventors: Shance LYU, Suzhou City (CN); Zhenguo SONG, Suzhou City (CN); Yue YANG, Suzhou City (CN); Xinghua SUN, Suzhou City (CN); Guiping GAO, Suzhou City (CN)

(73) Assignee: Suzhou Luxshare Technology Co., Ltd., Suzhou City (CN)

(21) Appl. No.: 18/765,642

(22) Filed: Jul. 8, 2024

(30) Foreign Application Priority Data
Dec. 22, 2023 (CN) 202311787758.X

(51) Int. Cl. H01P 1/203; H01P 1/04

(52) U.S. Cl. CPC H01P 1/20309; H01P 1/04

(57) ABSTRACT

Provided is a TM-mode dielectric filter including a housing, a support structure, a dielectric resonant rod, a cover plate, a buffer pad, and a plurality of tuning assemblies. A resonant cavity is disposed on the housing, the support structure is disposed on a bottom of the resonant cavity, one end of the dielectric resonant rod is mounted on the support structure, multiple adjustment holes are disposed on the dielectric resonant rod, the cover plate is connected to the housing and covers an opening of the resonant cavity, the buffer pad is disposed in the resonant cavity, covers another end of the dielectric resonant rod, and is sandwiched between the dielectric resonant rod and the cover plate, and the plurality of tuning assemblies is disposed on the cover plate, and each adjustment hole of the multiple adjustment holes is configured with a corresponding one of the plurality of tuning assemblies.

### CROSS-REFERENCE TO RELATED APPLICATION(S)

This application claims priority to Chinese Patent Application No. 202311787758X filed Dec. 22, 2023, the disclosure of which is incorporated herein by reference in its entirety.

### TECHNICAL FIELD

The present disclosure relates to the technical field of radio frequency products, and in particular, to a TM-mode dielectric filter.

### BACKGROUND

A transverse magnetic (TM)-mode dielectric filter uses a dielectric resonant rod with a high dielectric constant and a low loss, has advantages of small volume and high performance, and is applicable to the communication base station with the high sensitivity requirement.

The TM-mode dielectric filter requires two end surfaces of the dielectric resonant rod to be reliably braced and fixed. Existing TM-mode dielectric filters mainly include a housing, a metal resonant rod, a dielectric resonant rod, a cover plate, and a plurality of tuning assemblies. The metal resonant rod and the dielectric resonant rod are mounted in the housing in a stacked manner, the cover plate is fixed to an open end of the housing to press against the dielectric resonant rod, and the plurality of tuning assemblies is disposed on the cover plate to cooperate with the metal resonant rod and the dielectric resonant rod. In order to ensure the tight fit between the metal resonant rod, the dielectric resonant rod and the cover plate, an elastic structure is generally disposed between the metal resonant rod and the dielectric resonant rod, or the elastic deformation of the metal resonant rod braces the dielectric resonant rod, or the elastic deformation of the cover plate braces the dielectric resonant rod, so that the bracing contact of the two end surfaces of the dielectric resonant rod is poor, the stress is unbalanced, and thus the performance of the TM-mode dielectric filter is affected.

### SUMMARY

The present disclosure provides a TM-mode dielectric filter, which can ensure the good bracing contact between two end surfaces of a dielectric resonant rod, and enable the stress of the dielectric resonant rod to be more balanced.

The TM-mode dielectric filter includes a housing, a support structure, a dielectric resonant rod, a cover plate, a buffer pad and a plurality of tuning assemblies. A resonant cavity is disposed on the housing. The support structure is disposed at a bottom of the resonant cavity. One end of the dielectric resonant rod is mounted on the support structure, and multiple adjustment holes are disposed on the dielectric resonant rod. The cover plate is connected to the housing and covers an opening of the resonant cavity in a sealing manner. The buffer pad is disposed in the resonant cavity, covers another end of the dielectric resonant rod, and is sandwiched between the dielectric resonant rod and the cover plate. The plurality of tuning assemblies is disposed on the cover plate, where each adjustment hole of the multiple adjustment holes is configured with a corresponding one of the plurality of tuning assemblies.

In an embodiment, the buffer pad is a metal plate.

In an embodiment, the buffer pad is a metal dome, a deformation groove is formed on one side of the metal dome, a deformation boss corresponding to the deformation groove is formed on another side of the metal dome, an opening of the deformation groove faces the dielectric resonant rod, and the deformation boss is abutted against the cover plate

In an embodiment, a central through hole is disposed on the dielectric resonant rod, the multiple adjustment holes are uniformly distributed and disposed around an outer circumference of the central through hole, a central clamping barrel is formed on another side of the metal dome, and the central clamping barrel is clamped in the central through hole

In an embodiment, the support structure includes a metal resonant rod, the metal resonant rod includes a support pillar and a bracket plate connected to each other, a diameter of the support pillar is less than a diameter of the bracket plate, the bracket plate is abutted against the dielectric resonant rod, and the support pillar is abutted against the housing

In an embodiment, the support structure includes a metal resonant rod, the metal resonant rod includes a support pillar and a tray connected to each other, a diameter of the support pillar is less than a diameter of the tray, a bracket groove is disposed on a side of the tray facing away from the support pillar, one end of the dielectric resonant rod facing the metal resonant rod is provided with a positioning block, the positioning block is clamped in the bracket groove, and the support pillar is abutted against the housing

In an embodiment, the support structure includes a metal resonant rod, the metal resonant rod includes a support pillar and a clamping pillar connected to each other, one end of the dielectric resonant rod facing the metal resonant rod is provided with a positioning groove, the clamping pillar is clamped in the positioning groove, and the support pillar is abutted against the housing

In an embodiment, the TM-mode dielectric filter further includes a lock-joint member, where a side wall of the dielectric resonant rod is provided with a lock-joint hole communicating with the positioning groove, and the lock-joint member is disposed in the lock-joint hole and connected to the clamping pillar

In an embodiment, the support structure includes a metal resonant rod and a mounting table integrally formed in a bottom of the resonant cavity, the metal resonant rod is mounted on the mounting table, and the dielectric resonant rod is mounted on the metal resonant rod

In an embodiment, further including a fastener, where an accommodation groove is disposed on a side of the metal resonant rod facing the dielectric resonant rod, the fastener is disposed in the accommodation groove, and one end of the fastener penetrates through a bottom of the accommodation groove and is connected to the mounting table.

Beneficial effects of the present disclosure are as follows.

The support structure cooperates with the buffer pad to brace two ends of the dielectric resonant rod, the buffer pad covers the end surface of the dielectric resonant rod, whereby the structure is simpler and the use is more reliable, the good bracing contact with the dielectric resonant rod is ensured, so that the stress of the dielectric resonant rod is more balance, the size of the TM-mode dielectric filter can be effectively reduced, and the stability of the TM-mode dielectric filter is improved.

In the TM-mode dielectric filter in this embodiment, the dielectric resonator rod is a dual-mode resonator, a single dielectric may generate two co-frequency resonator frequencies, and a dual-end short circuit manner is used, so that the size of the product can be effectively reduced, the size of the filter can be effectively reduced by about 30%, a maximum field strength of the resonator can be effectively reduced, a power indicator of the filter can be effectively improved, a structure of the cover plate can be simplified, the stability of the product can be improved, a quality factor of the resonator can be improved by loading a high dielectric constant dielectric, thereby improving the insertion loss of the filter. A form of a support structure at a bottom of the dielectric resonator rod is not fixed, and specifically, the form of the support structure at the bottom of the dielectric resonator rod may be transformed according to a use scenario. The cover plate may be connected to the housing in a welding manner, whereby an elastic structure is canceled. The buffer pad is added between the cover plate and the dielectric resonant rod, thereby avoiding the dielectric crack problem caused by a large difference in an expansion coefficient between the cover plate and the dielectric resonant rod. The buffer pad between the cover plate and the dielectric resonant rod is made of a brass series material or a purple copper series material with good ductility. The buffer pad may be press-connected to the dielectric resonant rod through an interference compression or welding or in a welding manner, so that the volume of the conventional comb filter can be effectively reduced. A welding form is used between the dielectric resonant rod and the support structure, since the dielectric expansion coefficient is close to that of the iron material, the deformation amount generated at high and low temperatures is relatively small, and the support structure at the bottom is made of 1215 steel or DC04 or 08A steel.

### BRIEF DESCRIPTION OF DRAWINGS

FIG. 1 is a schematic structural diagram of a first TM-mode dielectric filter according to an embodiment of the present disclosure;

FIG. 2 is a sectional view of a first TM-mode dielectric filter according to an embodiment of the present disclosure;

FIG. 3 is a schematic structural diagram of a housing of a first TM-mode dielectric filter according to an embodiment of the present disclosure;

FIG. 4 is a schematic structural diagram of a cooperation of a metal resonant rod and a dielectric resonant rod of a first TM-mode dielectric filter according to an embodiment of the present disclosure;

FIG. 5 is a sectional view of a cooperation of a metal resonant rod and a dielectric resonant rod of a first TM-mode dielectric filter according to an embodiment of the present disclosure;

FIG. 6 is a schematic structural diagram of a metal plate of a first TM-mode dielectric filter according to an embodiment of the present disclosure;

FIG. 7 is a sectional view of a second TM-mode dielectric filter according to an embodiment of the present disclosure;

FIG. 8 is a schematic structural diagram of a metal resonant rod of a second TM-mode dielectric filter according to an embodiment of the present disclosure;

FIG. 9 is a sectional view of a third TM-mode dielectric filter according to an embodiment of the present disclosure;

FIG. 10 is a schematic diagram of a disassembly structure of a metal resonant rod, a dielectric resonant rod, and a lock-joint member of a third TM-mode dielectric filter according to an embodiment of the present disclosure;

FIG. 11 is a schematic structural diagram of a dielectric resonant rod of a third TM-mode dielectric filter according to an embodiment of the present disclosure;

FIG. 12 is a sectional view of a fourth TM-mode dielectric filter according to an embodiment of the present disclosure;

FIG. 13 is a schematic structural diagram of a position of a metal dome of a fourth TM-mode dielectric filter according to an embodiment of the present disclosure;

FIG. 14 is a schematic structural diagram of another position of a metal dome of a fourth TM-mode dielectric filter according to an embodiment of the present disclosure;

FIG. 15 is a sectional view of a fifth TM-mode dielectric filter according to an embodiment of the present disclosure; and

FIG. 16 is a schematic structural diagram of a housing of a fifth TM-mode dielectric filter according to an embodiment of the present disclosure.

### REFERENCE LIST

1 housing
2 support structure
21 metal resonant rod
200 accommodation groove
211 support pillar
2111 sleeving groove
212 bracket plate
213 tray
2131 notch
214 clamping pillar
2141 deformation hole
22 mounting table
221 bottom support portion
222 clamping portion
23 reference table
3 dielectric resonant rod
31 adjustment hole
32 central through hole
33 positioning block
34 positioning groove
35 lock-joint hole
4 cover plate
5 buffer pad
51 deformation groove
52 deformation boss
53 central clamping barrel
6 tuning assembly
61 adjustment screw
62 locking nut
7 fastener
8 lock-joint member

### DETAILED DESCRIPTION

Embodiments of the present disclosure will be described in detail below, examples of the described embodiments are shown in the accompanying drawings, where same or similar reference numerals refer to same or similar parts or parts having same or similar functions throughout. The embodiments described below with reference to the accompanying drawings are exemplary, are intended to explain the present disclosure, and are not be construed as limiting the present disclosure.

In the description of the present disclosure, unless otherwise expressly specified and limited, the term “connected to each other”, “connected”, or “fixed” is to be construed in a broad sense, for example, as securely connected, or detachably connected; mechanically connected or electrically connected; directly connected to each other, indirectly connected to each other via an intermediary, internal connection between two elements, or interaction between two elements. For those of ordinary skill in the art, specific meanings of the preceding terms in the present disclosure may be understood based on specific situations.

In the description of the present disclosure, unless otherwise expressly specified and limited, a first feature being “on” or “under” a second feature may include the first feature and the second feature being in direct contact, or may include the first feature and the second feature not being in direct contact but being in contact with each other through an additional feature therebetween. Moreover, the first feature being “on”, “above” or “over” the second feature includes the first feature being directly on, above or over and obliquely on, above or over the second feature, or simply indicates that the first feature is at a higher level than the second feature. The first feature being “under”, “below” or “underneath” the second feature includes the first feature being directly under, below or underneath and obliquely under, below or underneath the second feature, or simply represents that the first feature is at a lower level than the second feature.

The technical schemes of the present disclosure are further explained hereinafter in conjunction with accompanying drawings and the specific implementation mode.

### Embodiment One

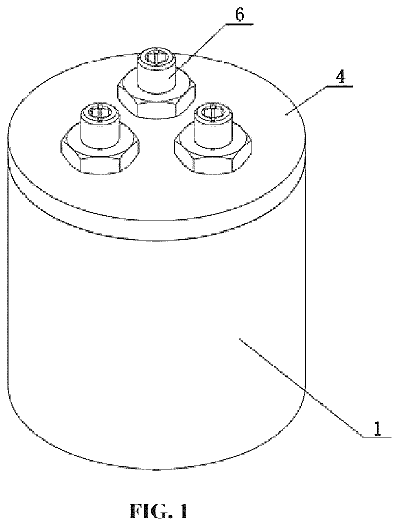

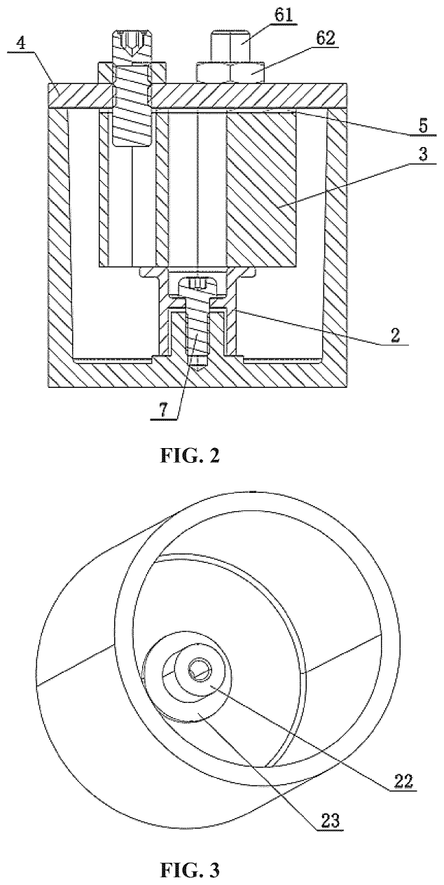

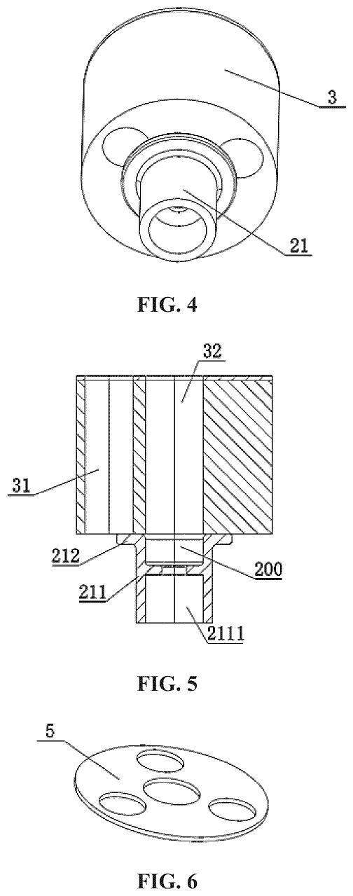

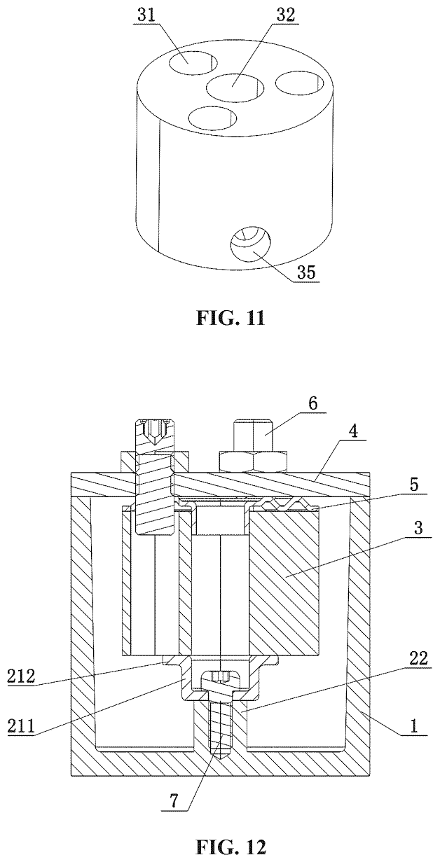

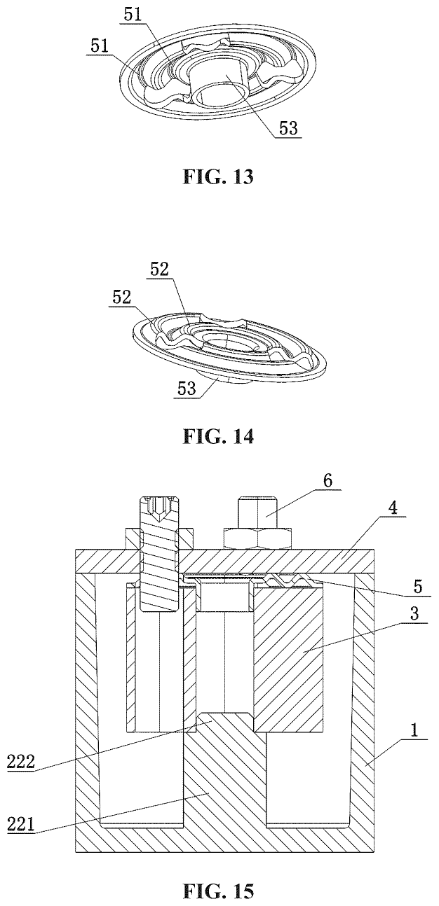

As shown in FIG. 1 to FIG. 16, the present disclosure provides a TM-mode dielectric filter. The TM-mode dielectric filter includes a housing 1, a support structure 2, a dielectric resonant rod 3, a cover plate 4, a buffer pad 5 and a plurality of tuning assemblies 6. A resonant cavity is disposed on the housing 1. The support structure 2 is disposed at a bottom of the resonant cavity. One end of the dielectric resonant rod 3 is mounted on the support structure 2, and multiple adjustment holes 31 are disposed on the dielectric resonant rod 3. The cover plate 4 is connected to the housing 1 and covers an opening of the resonant cavity in a sealing manner. The buffer pad 5 is disposed in the resonant cavity, covers another end of the dielectric resonant rod 3, and is sandwiched between the dielectric resonant rod 3 and the cover plate 4. The plurality of tuning assemblies 6 is disposed on the cover plate 4, where each adjustment hole of the multiple adjustment holes 31 is configured with a corresponding one tuning assembly 6.

In the present disclosure, the support structure 2 cooperates with the buffer pad 5 to brace two ends of the dielectric resonant rod 3, the buffer pad 5 covers the end surface of the dielectric resonant rod 3, whereby the structure is simpler and the use is more reliable, the good bracing contact with the dielectric resonant rod 3 is ensured, so that the stress of the dielectric resonant rod 3 is more balance, the size of the TM-mode dielectric filter can be effectively reduced, and the stability of the TM-mode dielectric filter is improved.

Specifically, a central through hole 32 is disposed on the dielectric resonant rod 3, the multiple adjustment holes 31 are uniformly distributed and disposed around an outer circumference of the central through hole 32, so as to facilitate the alignment mounting of the dielectric resonant rod 3.

More specifically, the dielectric resonant rod 3 is a cylindrical structure, the central through hole 32 is disposed in a penetrating manner at an axis position of the dielectric resonant rod 3, three adjustment holes 31 are provided, and three tuning assemblies 6 are correspondingly provided.

More specifically, the housing 1 is a cylindrical structure, and the diameter of the resonant cavity gradually decreases from an opening to a bottom.

In this embodiment, the tuning assembly 6 includes an adjustment screw 61 and a locking nut 62. The adjustment screw 61 is screwed to the cover plate 4, and an axis of the adjustment screw 61 is parallel to an axis of the dielectric resonant rod 3. One end of the adjustment screw 61 extends into a corresponding adjustment hole 31, and the locking nut 62 is screwed to the adjustment screw 61, and is abutted against a side of the cover plate 4 facing away from the housing 1.

In the TM-mode dielectric filter in this embodiment, the dielectric resonator rod 3 is a dual-mode resonator, a single dielectric may generate two co-frequency resonator frequencies, and a dual-end short circuit manner is used, so that the size of the product can be effectively reduced, the size of the filter can be effectively reduced by about 30%, a maximum field strength of the resonator can be effectively reduced, a power indicator of the filter can be effectively improved, a structure of the cover plate 4 can be simplified, the stability of the product can be improved, a quality factor of the resonator can be improved by loading a high dielectric constant dielectric, thereby improving the insertion loss of the filter. A form of a support structure 2 at a bottom of the dielectric resonator rod 3 is not fixed, and specifically, the form of the support structure at the bottom of the dielectric resonator rod may be transformed according to a use scenario. The cover plate 4 may be connected to the housing 1 in a welding manner, whereby an elastic structure is canceled. The buffer pad 5 is added between the cover plate 4 and the dielectric resonant rod 3, thereby avoiding the dielectric crack problem caused by a large difference in an expansion coefficient between the cover plate 4 and the dielectric resonant rod 3. The buffer pad 5 between the cover plate 4 and the dielectric resonant rod 3 is made of a brass series material or a purple copper series material with good ductility. The buffer pad 5 may be press-connected to the dielectric resonant rod 3 through an interference compression or welding or in a welding manner, so that the volume of the conventional comb filter can be effectively reduced. A welding form is used between the dielectric resonant rod 3 and the support structure 2, since the dielectric expansion coefficient is close to that of the iron material, the deformation amount generated at high and low temperatures is relatively small, and the support structure 2 at the bottom is made of 1215 steel or DC04 or 08A steel.

### Embodiment Two

As shown in FIG. 1 to FIG. 11, on the basis of the embodiment one, this embodiment provides a TM-mode dielectric filter. The buffer pad 5 is a metal plate, so that the good bracing contact with the dielectric resonant rod 3 is further ensured, the stress of the dielectric resonant rod 3 is more balanced, and the size of the TM-mode dielectric filter can be further reduced.

Specifically, the metal plate is a circular plate sheet, and a size structure of the metal plate is the same as a size structure of a cross-section of the dielectric resonant rod 3, so that a top end surface of the dielectric resonant rod 3 is completely covered.

More specifically, corresponding to positions of the central through hole 32 and the adjustment hole 31 of the dielectric resonant rod 3, through holes with a same size structure are disposed on the metal plate, and after one end of the adjustment screw 61 penetrates through the through hole on the metal plate, the adjustment screw 61 extends into the corresponding adjustment hole 31.

In this embodiment, a material of the metal plate is T2 pure copper, 1215 steel, or H62 brass, and is connected to a silver plating layer at the end of the dielectric resonant rod 3 in a welding manner.

During assembly, the metal plate and the dielectric resonant rod 3 are welded together firstly, then mounted in the resonant cavity as a whole, and finally, the metal plate and the cover plate 4 are welded by means of coating solder paste, reflow welding or induction welding.

### Embodiment Three

As shown in FIG. 12 to FIG. 16, on the basis of the embodiment one, this embodiment provides a TM-mode dielectric filter. The buffer pad 5 is a metal dome, a deformation groove 51 is formed on one side of the metal dome, a deformation boss 52 corresponding to the deformation groove 51 is formed on another side of the metal dome, an opening of the deformation groove 51 faces the dielectric resonant rod 3, and the deformation boss 52 is abutted against the cover plate 4. Through the above-described arrangement, the bracing acting force of the buffer pad 5 on the dielectric resonant rod 3 is improved.

Specifically, a central clamping barrel 53 is formed on a side of the metal dome, and the central clamping barrel 53 is clamped in the central through hole 32. Through the above-described arrangement, the alignment mounting of the buffer pad 5 and the dielectric resonant rod 3 is enabled to be more accurate.

More specifically, the metal dome is circular, and a size structure of an outer circumference of the metal dome is the same as a size structure of a cross-section of the dielectric resonant rod 3, so that a top end surface of the dielectric resonant rod 3 is completely covered. The deformation groove 51 is an annular groove, and an axis of the metal dome is used as a shaft.

In this embodiment, the metal dome is formed by stamping a circular metal sheet, two deformation grooves 51 are provided, the two deformation grooves 51 are coaxially disposed, and one deformation groove 51 is sleeved on an outer circumference of another deformation groove 51. Corresponding to the stamping processing of two deformation grooves 51 at one side of the metal dome, two annular deformation bosses 52 are synchronously formed on another side of the metal dome. One through hole is formed at an axial position of the metal dome by means of stamping, a central clamping barrel 53 is formed around the through hole at a side of the metal dome, and a through hole at the axial position of the metal dome penetrates through the central clamping barrel 53, and communicates with the central through hole 32 of the dielectric resonant rod 3. Corresponding to the position of the adjustment hole 31 of the dielectric resonant rod 3, through holes of the same size and structure are disposed on the metal dome.

### Embodiment Four

As shown in FIG. 1 to FIG. 11, on the basis of any one of the embodiment one to the embodiment three, this embodiment provides a TM-mode dielectric filter. The support structure 2 includes a metal resonant rod 21, and the metal resonant rod 21 is mounted in a resonant cavity and braces a bottom end of the dielectric resonant rod 3. Therefore, when the maintenance replacement needs to be performed, the dielectric resonant rod 3 can be removed from the resonant cavity with the metal resonant rod 21, and the structure of the resonant cavity does not need to be damaged.

More specifically, the support structure 2 further includes a mounting table 22 integrally formed in a bottom of the resonant cavity, and the metal resonant rod 21 is mounted on the mounting table 22. The mounting table 22 is disposed so that the positioning mounting of the metal resonant rod 21 is more accurate.

In this embodiment, the TM-mode dielectric filter further includes a fastener 7. An accommodation groove 200 is disposed on a side of the metal resonant rod 21 facing the dielectric resonant rod 3, the fastener 7 is disposed in the accommodation groove 200, and one end of the fastener 7 penetrates through a bottom of the accommodation groove 200 and is connected to the mounting table 22. Through the above-described arrangement, the metal resonant rod 21 is enabled to be assembled and disassembled in the resonant tank more conveniently and reliably.

More specifically, a threaded groove is disposed on the mounting table 22, and the fastener 7 is screwed to the threaded groove. Through the above-described arrangement, the fastener 7 is enabled to be more conveniently detached from the housing 1.

In this embodiment, the fastener 7 is a bolt, a head of the bolt is located in the accommodation groove 200, and a screw portion penetrates through the bottom of the accommodation groove 200 and is screwed to the mounting table 22. In other embodiments, the fastener 7 may also be a pin and is clamped in the metal resonant rod 21 and the mounting table 22.

### Embodiment Five

As shown in FIG. 1 to FIG. 6, on the basis of the embodiment four, this embodiment provides a TM-mode dielectric filter. The metal resonant rod 21 includes a support pillar 211 and a bracket plate 212 connected to each other, a diameter of the support pillar 211 is less than a diameter of the bracket plate 212, the bracket plate 212 is abutted against the dielectric resonant rod 3, and the support pillar 211 is abutted against the housing 1. The bracket plate 212 is disposed so that the contact area between the metal resonant rod 21 and the dielectric resonant rod 3 is increased, and the good bracing contact between the metal resonant rod 21 and the dielectric resonant rod 3 is ensured.

In this embodiment, the metal resonant rod 21 is a metal material, such as iron, stainless steel, or copper.

Specifically, one end of the dielectric resonant rod 3 facing the metal resonant rod 21 is provided with a silver plating layer, and the dielectric resonant rod 3 is connected to the metal resonant rod 21 in a welding manner by using the silver plating layer. Through the above-described arrangement, the technical problem that the welding operation is difficult to be performed between the dielectric resonant rod 3 and the resonant cavity is overcome, moreover, when the maintenance replacement needs to be performed, the dielectric resonant rod 3 can be removed from the resonant cavity with the metal resonant rod 21, and the structure of the resonant cavity does not need to be damaged.

More specifically, the support pillar 211 is a cylinder, the bracket plate 212 is a disk, the support pillar 211 is coaxially connected to the bracket plate 212, the diameter of the bracket plate 212 is less than a diameter of the dielectric resonant rod 3, and the dielectric resonant rod 3 is connected to the bracket plate 212 in a welding manner by using the silver plating layer.

In this embodiment, one end of the support pillar 211 facing away from the bracket plate 212 is provided with a sleeving groove 2111, and the sleeving groove 2111 is sleeved on the outside of the mounting table 22. Through the above-described arrangement, the mounting and positioning of the metal resonant rod 21 in the resonant cavity is enabled to be more accurate. In other embodiments, as shown in FIG. 12 to FIG. 14, it is also possible that a bottom end of the support pillar 211 abuts directly against a top end of the mounting table 22. In other embodiments, an annular groove may be disposed around the support pillar 211 on a side of the bracket plate 212 facing away from the dielectric resonant rod 3.

More specifically, the support structure 2 further includes a reference table 23 integrally formed on the bottom of the resonant cavity, the mounting table 22 is integrally formed on the reference table 23, the mounting table 22 and a bottom of the positioning groove 34 are disposed at intervals, and the metal resonant rod 21 is abutted against the reference table 23. The reference table 23 is disposed so that the clamping interval between the metal resonant rod 21 and the buffer pad 5 can be adjusted more conveniently, whereby the dielectric resonant rod 3 is clamped and fixed more safely and reliably, and thus the damage to the bottom of the resonant cavity is avoided.

In this embodiment, a diameter of the mounting table 22 is less than a diameter of the reference table 23, the accommodation groove 200 extends from the bracket plate 212 to the support pillar 211, a sleeving groove 2111 is disposed at an end of the support pillar 211 facing away from the bracket plate 212, and a diameter of the accommodation groove 200 is equal to a diameter of the sleeving groove 2111.

More specifically, the central through hole 32 is in direct communication with the accommodation groove 200, and a diameter of the central through hole 32 is equal to the diameter of the accommodation groove 200, so that the fastener 7 can be conveniently inserted and removed after the dielectric resonant rod 3 and the metal resonant rod 21 are connected in a welding manner.

In the TM-mode dielectric filter in this embodiment, the dielectric resonator rod 3 is a dual-mode resonator, a single dielectric may generate two co-frequency resonator frequencies, and a dual-end short circuit manner is used, so that the size of the product can be effectively reduced, the size of the filter can be effectively reduced by about 30%, a maximum field strength of the resonator can be effectively reduced, a power indicator of the filter can be effectively improved, a structure of the cover plate 4 can be simplified, the stability of the product can be improved, a quality factor of the resonator can be improved by loading a high dielectric constant dielectric, thereby improving the insertion loss of the filter. A form of a support structure 2 at a bottom of the dielectric resonator rod 3 is not fixed, and specifically, the form of the support structure at the bottom of the dielectric resonator rod may be transformed according to a use scenario so as to adaptively adjust the structure and size. The cover plate 4 may be connected to the housing 1 in a welding manner, whereby an elastic structure is canceled. The metal plate or the metal dome is added between the cover plate 4 and the dielectric resonant rod 3, thereby avoiding the dielectric crack problem caused by a large difference in an expansion coefficient between the cover plate 4 and the dielectric resonant rod 3. The metal plate or the metal dome between the cover plate 4 and the dielectric resonant rod 3 is made of a brass series material or a purple copper series material with good ductility. The metal plate or the metal dome may be press-connected to the dielectric resonant rod 3 through an interference compression or welding or in a welding manner, so that the volume of the conventional comb filter can be effectively reduced. A welding form is used between the dielectric resonant rod 3 and the support structure 2, since the dielectric expansion coefficient is close to that of the iron material, the deformation amount generated at high and low temperatures is relatively small, and the metal resonant rod 21 at the bottom is made of 1215 steel or DC04 or 08A steel.

### Embodiment Six

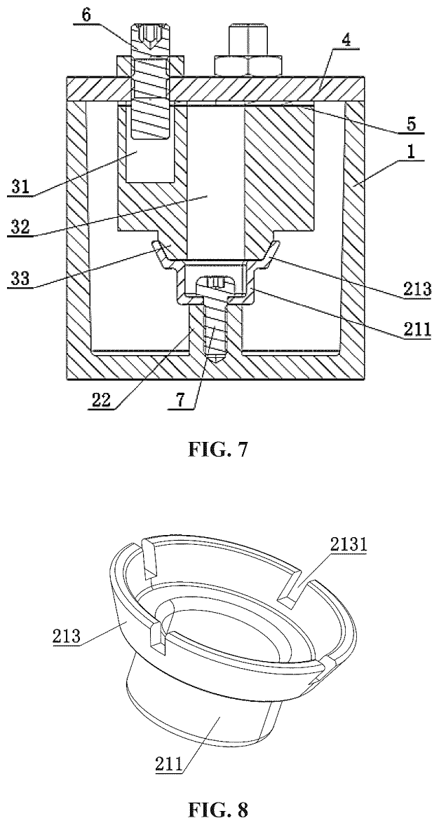

As shown in FIG. 7 and FIG. 8, on the basis of the embodiment four, this embodiment provides a TM-mode dielectric filter. The metal resonant rod 21 includes a support pillar 211 and a tray 213 connected to each other, a diameter of the support pillar 211 is less than a diameter of the tray 213, a bracket groove is disposed on a side of the tray 213 facing away from the support pillar 211, one end of the dielectric resonant rod 3 facing the metal resonant rod 21 is provided with a positioning block 33, the positioning block 33 is clamped in the bracket groove, and the support pillar 211 is abutted against the housing 1. The tray 213 is disposed so that the metal resonant rod 21 can further perform a radial definitive effect on the dielectric resonant rod 3 on the basis that the metal resonant rod 21 braces the dielectric resonant rod 3 in the axial direction.

In this embodiment, the metal resonant rod 21 is a metal material, such as iron, stainless steel, or copper.

Specifically, from the opening to the bottom, a diameter of the bracket groove gradually decreases, multiple notches 2131 communicating with an outer side of the tray 213 are disposed on a groove wall of the bracket groove, and the multiple notches 2131 are uniformly distributed and disposed around an axis of the tray 213. After the metal resonant rod 21 and the dielectric resonant rod 3 are assembled, the metal resonant rod 21 and the dielectric resonant rod 3 are interference fit in a height direction, so that the tray 213 more precisely limits the clamping of the positioning block 33. After the notch 2131 is provided, the tray 213 may absorb a machining tolerance of the metal resonant rod 21, the dielectric resonant rod 3, and the housing 1, and meanwhile, ensure the good contact with the dielectric resonant rod 3 to implement the fixed form of double-end grounding.

More specifically, the support pillar 211 is a cylindrical body, and a bottom end of the support pillar 211 is abutted against a top end of the mounting table 22. A tray 213 at a top end of the support pillar 211 is a circular disk, the accommodation groove 200 is disposed at the bottom of the bracket groove, the support pillar 211 is coaxially connected to the tray 213, the diameter of the tray 213 is less than the diameter of the dielectric resonant rod 3, the central through hole 32 is in direct communication with the accommodation groove 200, and the diameter of the central through hole 32 is equal to the diameter of the accommodation groove 200, so that the fastener 7 can be conveniently inserted and removed.

In this embodiment, one end of the dielectric resonant rod 3 facing the metal resonant rod 21 is provided with a silver plating layer, and the dielectric resonant rod 3 is connected to the bracket groove in a welding manner by using the silver plating layer. Through the above-described arrangement, the technical problem that the welding operation is difficult to be performed between the dielectric resonant rod 3 and the resonant cavity is overcome, moreover, when the maintenance replacement needs to be performed, the dielectric resonant rod 3 can be removed from the resonant cavity with the metal resonant rod 21, and the structure of the resonant cavity does not need to be damaged.

### Embodiment Seven

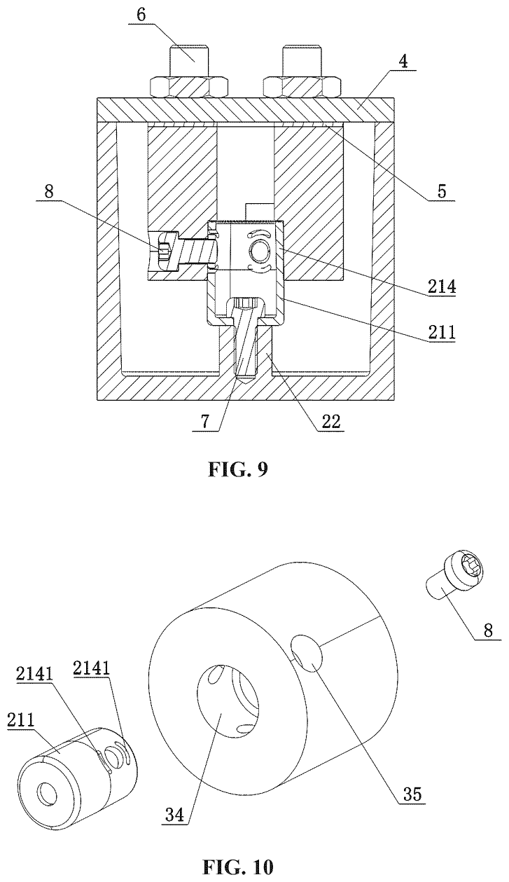

As shown in FIG. 9 to FIG. 11, on the basis of the embodiment four, this embodiment provides a TM-mode dielectric filter. The metal resonant rod 21 includes a support pillar 211 and a clamping pillar 214 connected to each other, one end of the dielectric resonant rod 3 facing the metal resonant rod 21 is provided with a positioning groove 34, the clamping pillar 214 is clamped in the positioning groove 34, and the support pillar 211 is abutted against the housing 1. Through the above-described arrangement, the disassembly and assembly between the metal resonant rod 21 and the dielectric resonant rod 3 are enabled to be more convenient.

Specifically, the TM-mode dielectric filter further includes a lock-joint member 8. A lock-joint hole 35 communicating with the positioning groove 34 is disposed on a side wall of the dielectric resonant rod 3, and the lock-joint member 8 is disposed in the lock-joint hole 35, and is connected to the clamping pillar 214. Through the above-described arrangement, the connection between the metal resonant rod 21 and the dielectric resonant rod 3 is enabled to be more reliable.

More specifically, both the support pillar 211 and the clamping pillar 214 are cylindrical structures, have a same diameter, and are coaxially connected. One end of the support pillar 211 facing away from the clamping pillar 214 is abutted against the top of the mounting table 22. The opening of the accommodation groove 200 is located at one end of the clamping pillar 214 facing away from the support pillar 211 and communicates with the central through hole 32 of the dielectric resonant rod 3, the accommodation groove 200 extends from the clamping pillar 214 to the support pillar 211, an outer wall of the clamping pillar 214 is provided with a threaded hole communicating with the accommodation groove 200, the lock-joint member 8 is a bolt, the lock-joint hole 35 is a countersunk hole, the head portion of the bolt is located in the countersunk bore, and the screw rod portion is screwed into the threaded hole of the clamping pillar 214.

More specifically, along the axial direction of the clamping pillar 214, a deformation hole 2141 is respectively disposed on two sides of the threaded hole on an outer wall of the clamping pillar 214, the deformation hole 2141 may accommodate a size change generated by the metal resonant rod 21, the dielectric resonant rod 3 and the housing 1 in the case of high and low temperatures during welding and use, the intersection and clamping portion of the metal resonant rod 21 and the dielectric resonant rod 3 has an inclination, and an interference fit is formed after the metal resonant rod 21 and the dielectric resonant rod 3 are mounted, so as to ensure the concentricity of the metal resonant rod 21 and the dielectric resonant rod 3 after the mounting, and to implement the fixed form of double-end grounding.

In this embodiment, the lock-joint member 8 and the lock-joint hole 35 are in one-to-one correspondence, three lock-joint members and three lock-joint holes are provided, an axis of the lock-joint hole 35 is perpendicular to an axis of the adjustment hole 31, and one lock-joint hole 35 is disposed between every two adjacent adjustment holes 31.

### Embodiment Eight

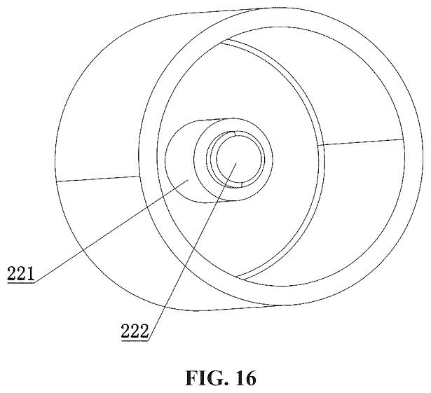

As shown in FIG. 15 and FIG. 16, on the basis of any one of the embodiment one to the embodiment three, this embodiment provides a TM-mode dielectric filter. The support structure 2 includes a mounting table 22 integrally formed in the bottom of the resonant cavity, and the dielectric resonant rod 3 is mounted on the mounting table 22, thereby simplifying the overall structure and facilitating the assembly.

In this embodiment, the mounting table 22 includes a bottom support portion 221 and a clamping portion 222 which are coaxially connected. A diameter of the bottom support portion 221 is greater than a diameter of the clamping portion 222, and is less than the diameter of the dielectric resonant rod 3. The bottom support portion 221 is connected to the bottom of the dielectric resonant rod 3, and is abutted against the bottom end of the dielectric resonant rod 3. The clamping portion 222 is clamped in the central through hole 32 of the dielectric resonant rod 3.

It should be understood that the above-described embodiments may be selectively combined as required on the basis that they can be achieved.

Apparently, the above-described embodiments of the present disclosure are merely examples for clearly illustrating the present disclosure and are not intended to limit the implementation modes of the present disclosure. Other variations or modifications in different forms may be made in light of the above description for those of ordinary skill in the art. This need not be, nor should it be exhaustive of all implementation modes. Any modifications, equivalents or improvements made within the spirit and principle of the present disclosure should be included within the scope of protection of the claims of the present disclosure.

What is claimed is:

1. A TM-mode dielectric filter, comprising:
a housing, wherein a resonant cavity is disposed on the housing;
a support structure disposed at a cavity bottom of the resonant cavity;
a dielectric resonant rod, wherein one end of the dielectric resonant rod is mounted on the support structure, and the dielectric resonant rod is provided with a plurality of adjustment holes;
a cover plate connected to the housing and covering an opening of the resonant cavity;
a buffer pad disposed in the resonant cavity, covering an other end of the dielectric resonant rod, and sandwiched between the dielectric resonant rod and the cover plate; and
a plurality of tuning assemblies disposed on the cover plate, wherein each adjustment hole of the plurality of adjustment holes is configured with a corresponding one of the plurality of tuning assemblies.

2. The TM-mode dielectric filter of claim 1, wherein the buffer pad is a metal plate.

3. The TM-mode dielectric filter of claim 1, wherein the buffer pad is a metal dome, a deformation groove is formed on one side of the metal dome, a deformation boss corresponding to the deformation groove is formed on an other side of the metal dome, an opening of the deformation groove is arranged to face to the dielectric resonant rod, and the deformation boss is abutted against the cover plate.

4. The TM-mode dielectric filter of claim 3, wherein the dielectric resonant rod is provided with a central through hole, the plurality of adjustment holes are uniformly distributed and disposed around an outer circumference of the central through hole, a central clamping barrel is formed on a side of the metal dome, and the central clamping barrel is clamped in the central through hole.

5. The TM-mode dielectric filter of claim 1, wherein the support structure comprises a metal resonant rod, the metal resonant rod comprises a support pillar and a bracket plate connected to each other, a diameter of the support pillar is less than a diameter of the bracket plate, the bracket plate is abutted against the dielectric resonant rod, and the support pillar is abutted against the housing.

6. The TM-mode dielectric filter of claim 1, wherein the support structure comprises a metal resonant rod, the metal resonant rod comprises a support pillar and a tray connected to each other, a diameter of the support pillar is less than a diameter of the tray, a bracket groove is disposed on a side of the tray facing away from the support pillar, an end of the dielectric resonant rod facing the metal resonant rod is provided with a positioning block, the positioning block is clamped in the bracket groove, and the support pillar is abutted against the housing.

7. The TM-mode dielectric filter of claim 1, wherein the support structure comprises a metal resonant rod, the metal resonant rod comprises a support pillar and a clamping pillar connected to each other, an end of the dielectric resonant rod facing the metal resonant rod is provided with a positioning groove, the clamping pillar is clamped in the positioning groove, and the support pillar is abutted against the housing.

8. The TM-mode dielectric filter of claim 7, further comprising a lock-joint member, wherein a side wall of the dielectric resonant rod is provided with a lock-joint hole communicating with the positioning groove, and the lock-joint member is disposed in the lock-joint hole and connected to the clamping pillar.

9. The TM-mode dielectric filter of claim 1, wherein the support structure comprises a metal resonant rod and a mounting table integrally formed in the bottom of the resonant cavity, the metal resonant rod is mounted on the mounting table, and the dielectric resonant rod is mounted on the metal resonant rod.

10. The TM-mode dielectric filter of claim 9, further comprising a fastener, wherein a side of the metal resonant rod facing the dielectric resonant rod is provided with an accommodation groove, the fastener is disposed in the accommodation groove, and an end of the fastener penetrates through the bottom of the accommodation groove and is connected to the mounting table.
